(19) United States
(12) Patent Application Publication
(10) Pub. No.: US 2003/0055586 A1
(43) Pub. Date: Mar. 20, 2003

(54) Regularization model for electrical resistance mapping

(75) Inventor: Wendell H. Mills JR., Granby, CT (US)

Correspondence Address: Russell W. Warnock, Esq., ALSTOM Power Inc., 2000 Day Hill Road, Windsor, CT, 06095, US

(73) Assignee: ALSTOM POWER N.V.

(21) Appl. No.: 09/934,105

(22) Filed: Aug. 21, 2001

(51) Int. Cl. G01R 27/00

(52) U.S. Cl. 702/65

(57) ABSTRACT

A regularization model for electrical resistance mapping of a combustion vessel such as, for example, a furnace 12 which combusts a fossil fuel, stabilizes the calculation of resistivities ρ from measured voltages u by incorporating third level and/or second level error minimization terms into the model. The third level error minimization term represents a third difference of resistivity ∇ₓ³ρₓ. The second level error minimization term represents a second difference of resistivity ∇²ρₓ. The third level and second level error minimization terms are deliberately defined to approximate local parabolic and linear behavior. A regularization constant γ is used to adjust the weight afforded the third level and/or second level error minimization terms. A system computer 62 uses numerical methods to solve the regularization model for values of resistivity ρ that result in a pre-established acceptable level of error E. The regularization model is incorporated into an on-line combustion vessel monitoring system.

### BACKGROUND OF THE INVENTION

The present invention relates to a method for evaluating data representing the electrical characteristics of a combustion vessel and, more particularly to a regularization model which minimizes error in calculations utilizing the data.

The walls of a combustion vessel are frequently made up of a series of heat exchange tubes filled with a heat exchange medium (typically water) and may be referred to as a “water wall”. Minerals may accumulate on the inside surface of the water tubes forming a layer referred to as boiler scale. Boiler scale impedes the transfer of heat from the combustion vessel wall to the heat exchange medium, impairing the efficiency of the boiler. Heat accumulates in the combustion vessel, raising the operational temperature of the wall of the combustion chamber. Higher operational temperatures may dangerously weaken the wall of the combustion chamber, resulting in premature failure.

One side of the water wall faces the combustion chamber and is exposed to the products of combustion, which may include hot gases, ash and corrosive combustion by-products. Combustion of fuels such as coal result in ash deposits on the inside surface of the water wall, impairing heat transfer from the heated gases in the combustion vessel to the water tubes. The coating of ash or slag on the combustion vessel wall impairs efficiency and must therefore be periodically removed.

The wall of a combustion vessel can corrode over time as a result of corrosive materials in the ash deposited by the fossil fuel consumed or physical degradation caused by, for example, solid waste consumed in a trash-to-energy plant. This corrosion reduces the wall thickness of the tubes. The walls of a combustion vessel must be maintained at a minimum thickness to reliably withstand the high pressure in the water tubes.

Proper maintenance of the combustion vessel typically requires periodic shutdown for inspection, cleaning and repair of critical components. If the expenses associated with plant shutdown are to be avoided without compromising safety, physical and operational conditions within the combustion vessel must be carefully monitored and evaluated to detect dangerous conditions. For these reasons, it would be desirable to provide non-intrusive on-line monitoring systems which evaluate the physical characteristics of critical portions of the combustion vessel itself to determine the temperature, heat flux and thickness of that portion of the combustion vessel.

One possible monitoring approach could be based upon known physical laws as they relate to the material (typically carbon steel) from which combustion vessel walls and water tubes are constructed. For example, it is known that the electric resistance in a conductor is proportional to the length of the conductor and inversely proportional to its cross-sectional area. The term resistivity as used herein is defined as the electrical resistance offered by a material to the flow of current, times the cross-sectional area of current flow and per unit length of current path; or the reciprocal of the conductivity. The resistivity of a conductor increases according to known laws with the temperature of the conductor. The term sheet resistivity for a two dimensional slab of material is defined as the resistivity per unit thickness.

It is known, for example, as disclosed in U.S. Pat. No. 3,721,897 to pass a constant current through a portion of the combustion chamber wall and measure the voltage drop across a known length of the wall. The resistance of that portion of the combustion vessel wall can be calculated using the constant current and measured voltage. Measurements taken during combustion vessel operation are compensated for temperature and compared to a base line resistance measurement. Increased resistance indicates a decreased area of the combustion vessel wall. If the resistance increases beyond a predetermined point, an unsafe condition, i.e., serious thinning of the water wall, is indicated and an unscheduled shutdown is justified. On the other hand, on-line monitoring may extend the period between scheduled shutdowns by indicating the plant is operating normally.

For these measurement systems, the nodes on the combustion vessel wall for application of current source, sink, and voltage measurements are conveniently arranged in a two dimensional matrix. Current is iteratively applied to and sunk from different locations in the matrix. For each current source/sink configuration, measurements are taken at nodes throughout the matrix and evaluated to determine any of the several aspects of interest of the combustion vessel wall.

Under ideal conditions, measurements can be made with an accuracy which will result in reliable indications of the physical and operational condition of the combustion vessel. However, given the limited accuracy of measuring devices and fluctuations in operational conditions within the boiler, calculated indications often contain an unacceptable level of error. In sum, there is a need in the art to reduce the error content and thus increase the accuracy of calculated combustion vessel evaluations based on measurements of the physical characteristics of the combustion vessel.

### SUMMARY OF THE INVENTION

A preferred embodiment of a method in accordance with the present invention comprises a regularization model which, when applied to data collected from a two dimensional grid of effectively equally spaced nodes on a combustion vessel wall, results in a minimization of the level of error in calculations utilizing the data.

In accordance with one aspect of the present invention, a grid or two-dimensional network of contact nodes is arranged on the outside surface of the water wall of a combustion vessel. A known current is iteratively imposed upon the network from a plurality of sources to a plurality of sinks. During each iteration of current source/sink, voltage measurements are taken between each of the nodes in the network. These voltage measurements comprise data that is used in calculations to determine the physical characteristics, e.g., resistance or temperature, of that portion of the combustion vessel wall being evaluated.

Another aspect of the present invention comprises application of a regularization model to the collected data for the purpose of minimizing the error resulting from the calculations. Recognizing that the equations designed to invert measured voltages into calculated resistivities are unstable, the invention applies second and third level error minimization terms to a least squares minimization model. Steepest descent numerical methods are applied to the resulting regularization model to converge on resistivity values that produce solutions to the regularization model at a predetermined low error value. An effectively stabilized calculation produces calculated resistivity values that accurately reflect the physical condition of the combustion vessel wall.

These and other objects, features, and advantages of the invention will become readily apparent to those skilled in the art upon reading the description of the preferred embodiments, in conjunction with the accompanying drawings

### BRIEF DESCRIPTION OF THE DRAWINGS

FIG. 1 is a schematic sectional view of a combustion vessel comprising a fossil fuel fired furnace and operable in accordance with the method of the present invention;

FIG. 2 is a schematic view of a matrix of nodes which could hypothetically be arranged on a portion of interest of a wall of a combustion vessel for supplying data in accordance with the method of the present invention;

FIG. 3 is an enlarged perspective sectional view of a portion of interest of a waterwall of the combustion vessel shown in FIG. 1; and

FIG. 4 is a schematic representation of a two dimensional matrix of nodes arranged on a portion of interest of a wall of a combustion vessel for supplying data in accordance with the method of the present invention.

### DETAILED DESCRIPTION OF THE PREFERRED EMBODIMENTS

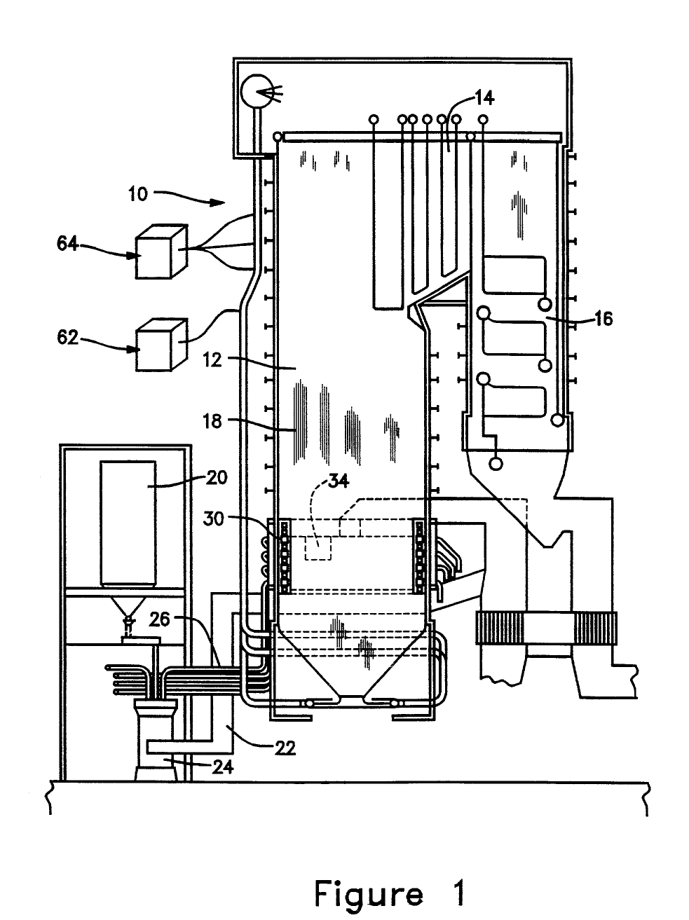

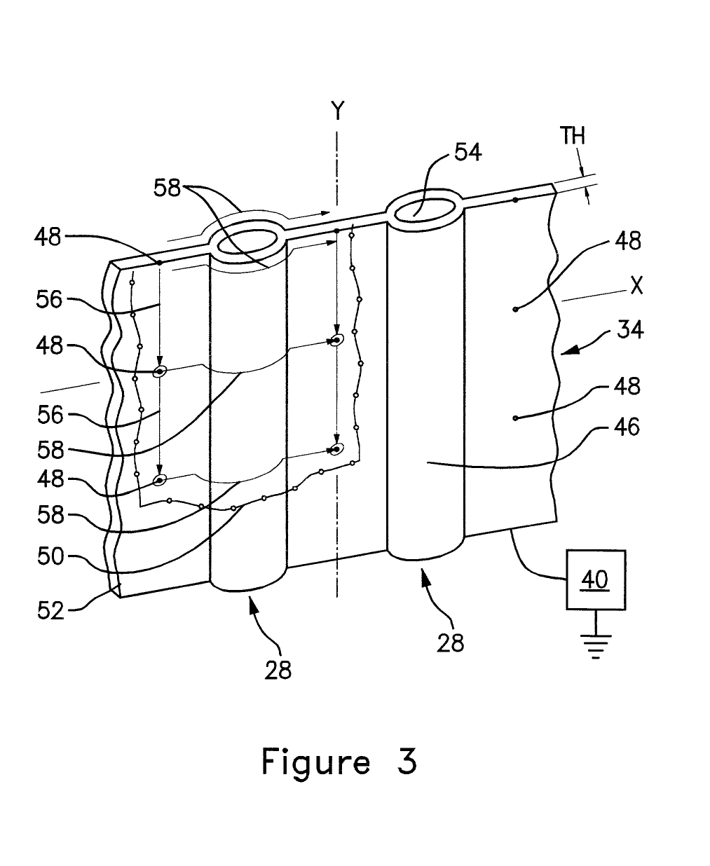

FIG. 1 illustrates an exemplary power generating unit 10 having a fossil fuel fired combustion vessel in the form of a furnace 12 and additionally including a horizontal gas pass 14 and a back pass 16. The furnace 12 has a fireside delimited by water walls 18 each having a plurality of water wall tubes 28, shown in FIG. 3, in which a heat exchange medium—namely, water—is circulated and which is converted into steam as a result of heating of the tubes 28 during the combustion of a fossil fuel such as, for example, coal, in the furnace 12. The power-generating unit 10 may include other conventional elements such as, for example, a turbine (not illustrated) for generating electricity under the motive action of steam passed thereover. Moreover, the horizontal gas pass 14 and the back pass 16 may comprise selected arrangements of economizers, super heaters and reheaters.

A coal feed apparatus 20 is operable to feed coal to a feeder which controls the rate of coal flow to a pulverizer 24. Hot primary combustion air is also fed to the pulverizer 24 via a duct 22 and this air carries pulverized coal through and out of the pulverizer 24 and thereafter through coal pipes 26 to several groups of coal nozzles. Each group of coal nozzles is mounted in a respective tangential firing windbox 30 that also each support a group of secondary air nozzles. The windboxes 30 introduce controlled flows of air and pulverized coal into the furnace 12 to effect the formation therein of a rotating fireball. The rotating fireball is a combustion process of the type which results in the release of material that contributes to depositions on the fireside surfaces of the water wall tubes 28. Carbon based combustion by-product builds up as slag and/or ash on the fireside surfaces of the water wall tubes 28.

It will be understood by one of ordinary skill in the art that certain combustion vessels, such as those fired by natural gas, do not corrode or waste in the manner of a combustion vessel fired by coal or solid waste. Therefore, the area of a segment of a combustion vessel wall between nodes in a natural gas fired combustion vessel, as compared to a segment of a combustion vessel wall of a fossil fuel-fired combustion vessel, will remain substantially constant over time. As a result, fluctuations in measured voltages in a natural gas fired combustion vessel will be substantially related to the increased resistance of the segment resulting from temperature changes. In calculations for this type of combustion vessel, i.e., natural gas fired, the area of the segment between nodes is known and the resulting fluctuations in the calculated resistance of the segment can be transformed according to known relationships into an accurate measure of the temperature of the segment.

On the other hand, in a solid waste or coal fired combustion vessel, corrosion or wastage of the walls of the combustion vessel occurs with relatively more regularity as compared to natural gas fired combustion vessels. Under such conditions, both the temperature and the area of the evaluated segment of combustion vessel produce changes in measured voltage between nodes. Under these circumstances, the temperature must be measured separately to eliminate multiple variables in the calculations. Following compensation for changes in temperature (which are known), changes in calculated resistances are attributable to changes in the cross-sectional area, e.g., thickness, of the evaluated portion of the combustion vessel.

In either of the above-described circumstances, due to well-known problems of accuracy and anomalies of measurement under operational conditions, the collected data inherently contains error. Furthermore, the problem of inverting the measured voltage into calculated resistivities using Kirchoff's law or its extension to zero line integrals is known as an ill posed (unstable) problem, i.e., small changes in measured voltages can produce large changes in calculated resistivities. Thus, measurement error which would otherwise be acceptable is amplified by the form of the calculation, typically leading to calculated resistivities having oscillatory behavior.

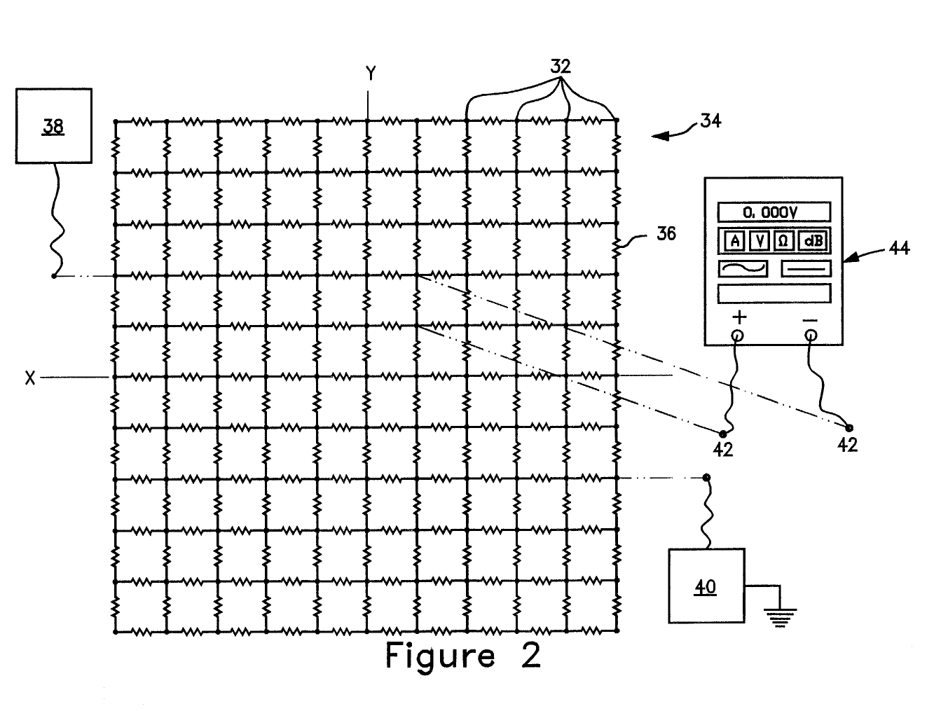

FIG. 2 is a schematic representation of a plurality of nodes 32 forming a matrix 34 which could hypothetically be arranged on a portion of interest of the wall of a combustion vessel. Segments of a water wall between respective adjacent pairs of the nodes 32 are characterized as unknown resistances 36 which are schematically shown in FIG. 2 as non-linear line segments extending between the respective adjacent pairs of the nodes 32. For the purposes of discussion, the matrix 34 is treated as a two-dimensional surface extending in the X (horizontal) and Y (vertical) directions. The four-wire technique is iteratively utilized to obtain sets of data comprising voltage measurements between nodes 32 in the matrix 34. The four-wire technique applies a source of constant current 38 and a sink 40 (ground) at various locations in the matrix 34. For each iteration of current source/sink, voltage measurements are taken by connecting the leads 42 of a volt meter 44 between nodes 32 in the matrix 34. The resulting sets of voltage measurements are the data from which the values of the unknown 1 resistances 36 are calculated.

Calculating the remaining thickness of an ohmic material (e.g., carbon steel) is relatively simple for an isothermal material with uniform cross-section. However, calculating the remaining thickness of an ohmic material comprised in a water wall is relatively more complicated. FIG. 3 shows a portion of interest of a water wall 18 of the furnace 12 shown in FIG. 1. The water wall comprises individual water tubes 28 laid side by side connected by webs of material as illustrated. The water wall 18 has an inner facing surface 46 that faces the interior of the furnace 12. A plurality of nodes 48 form a matrix 50 arranged on the outside surface 52 of the water wall 18 such that these nodes are not directly exposed to the radiation heat and other thermal conditions to which the inner facing surface 46 of the water wall 18 is exposed by virtue of its direct exposure to the combustion of fossil fuel in the furnace 12. For example, the inner facing surface 46 of the water wall 18 can be exposed to temperatures up to 900° C. (900 degrees C.). The nodes 48 need not be in the form of additional physical structures on the water wall 18 but can, instead, be arbitrarily designated locations on the water wall. The nodes 48 are locations on the water wall 18 schematically shown as circles. The matrix 50 can be any arbitrarily designated arrangement of nodes 48 and need not be physically delimited by any defined structure of the water wall 18. Thus, the matrix 50 is schematically shown in FIG. 3 in broken lines. The water tubes 28 in the illustrated embodiment are oriented generally parallel to the Y axis and include an interior surface 54. Nodes 48 are, for purposes of calculation, effectively equidistantly spaced from one another in the X and Y directions forming a two dimensional matrix, whereby the term “effectively equidistantly spaced” is to be understood as encompassing both the situation in which the respective nodes of adjacent pairs of the nodes 48 are at a uniform spacing from one another as well as the situation in which the nodes 48 are not physically equidistant from one another but their relationships can be mathematically adjusted so that, for purposes of calculation, they behave as equidistantly spaced nodes as discussed below.

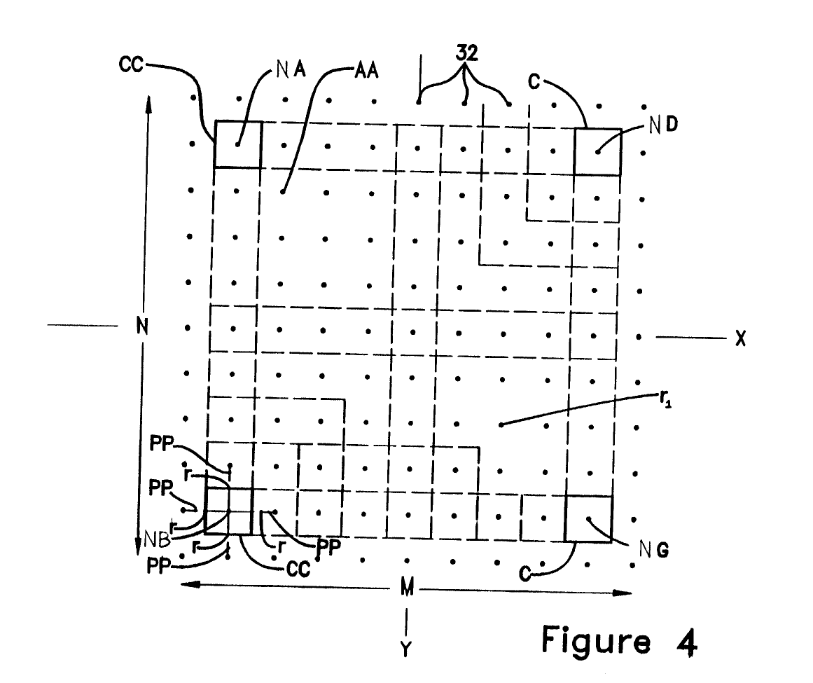

Current from constant current source 38 entering at the upper left-hand node has a simple path 56, schematically shown by arrows in FIG. 4, parallel to the Y axis. Current flow parallel to the X axis takes a relatively more complicated path 58, schematically shown by arrows in FIG. 4. Thus, the sheet resistivity of the water wall parallel to the X axis will be different from the sheet resistivity of the water wall parallel to the Y axis. However, this fact can be compensated for by establishing the ratio R of the sheet resistivity parallel to the Y axis to the sheet resistivity parallel to the X axis. This relationship is consistent enough over a range of time and temperature so that it does not unduly effect the resulting calculations. The calculated resistances are ultimately used to determine the thickness TH or temperature of the portion of the water wall being evaluated.

While the electrical and physical phenomena in connection with electrical resistance measurement in a water wall of a furnace have been discussed in connection with FIGS. 2 and 3, reference is now made to FIG. 4 which illustrates a mathematical representation of the two dimensional matrix 34 shown in FIG. 2. The matrix 34 is illustrated as a two dimensional grid having eleven nodes 32 on a side. The X and Y axes are arbitrarily drawn to have their origin xₒ, yₒ in the center of the illustrated grid. Because a mathematical correction can be used for unequally spaced nodes on an irregular mesh to adjust the sheet resistivities of the grid with respect to the X and Y axes, the grid is illustrated and mathematically treated as a grid of equidistantly spaced nodes 32.

According to Kirchoff's law, the total change of potential around any closed electrical circuit is zero. When applied to the matrix 34, Kirchoff's law dictates that, for any closed rectangular curve CC, the sum of the currents flowing out of CC must equal the sum of all current sources inside CC.

As previously stated, several iterations of current source and sink are applied to the matrix of nodes 32 on the waterwall. Each pattern of current sources and sinks applied to the matrix 34 will produce a different set of voltage measurements. A large number of current source/sink iterations will produce more sets of voltage measurements with the potential for increased accuracy. However, it has been found that a smaller number of carefully selected current source/sink iterations produce results having acceptable accuracy.

With reference to FIG. 4, the letters NA, NB, ND, and NG designate four interior corner nodes 32. One pattern or sequence of current source/sink iterations that has produced acceptable results include the following steps (a)-(h):

(a) apply current to node NA and sink to node NB;

(b) make voltage measurements;

(c) apply current to node ND and sink to node NG;

(d) make voltage measurements;

(e) apply current to node NA and sink to node NG;

(f) make voltage measurements;

(g) apply current to node ND and sink to node NB; and

(h) make voltage measurements.

Alternatively, further interior nodes, such as AA, may be used to produce comparable results. The above-described iterations result in four sets of voltage measurements.

A particularly important aspect of the invention relates to how the voltage data are utilized to produce useful calculated values for the resistivity of that portion of the waterwall being evaluated. The voltage measurements allow calculation of voltage drops Δu between nodes 32 by simple subtraction. In accordance with a particular aspect of the invention, data sets comprising values for Δu may be statistically manipulated to eliminate anomalous values. The goal of the invention is to reduce error in the calculation of resistivities and improving the quality of the input data by such statistical means has proven a useful preliminary step.

A preferred embodiment of the invention uses the voltage drop data Δu in calculations designed to evaluate closed rectangular curves CC that surround at least one node 32. With reference to FIG. 4, patterns of closed rectangular curves CC are selected to include all possible curves CC which include each of the four interior corner nodes NA, NB, ND and NG.

This is accomplished by beginning with a curve in each corner that surrounds only the interior corner node NA, NB, ND or NG. That curve (for purposes of discussion surrounding node NB) is evaluated in a manner to be described below. The curve is then expanded to surround an additional node in the x direction, for example. This new curve is evaluated. The curve is further expanded by an additional node in the x direction until the opposite interior corner node is surrounded by the curve, which now surrounds one row of nodes 32 extending from NB to NG. The process begins again with a new curve CC that surrounds two nodes, the interior corner node NB and an additional node in the y direction. This new curve CC is then expanded in the x direction and evaluated after each expansion. The curves CC are expanded in the y direction and across the matrix until all possible curves containing the interior corner node NB are evaluated. This process is repeated for each of the four interior corner nodes NA, NB, ND, and NG and for each set of voltage measurements.

One possible mathematical model of the physics that forms the basis for evaluating each curve CC is described as follows:

Treat the waterwall as a two dimensional slab and assume no current variations through the thickness. The voltage u(x,y), which is defined at any point (x,y) on the waterwall, ideally satisfies the following line integral equations around any rectangular two dimensional curve CC on the waterwall [Equation 1]:

$${J}_{n e t} ( u ) = {∮}_{C} i ( s ) ⅆ n - {S}_{C} = {∮}_{C} \frac{1}{{ρ}_{r}} {( \frac{ⅆ u}{ⅆ {s}_{n}} )}_{r} ⅆ s - {S}_{C} = 0$$

where r is any point on CC at arc length S, i(s) is the current at arc length s on CC flowing in the direction of the outer normal PP to CC, S_{C} is the sum of all current source/sinks within CC, du/dsₙ is the voltage gradient normal to the curve at point r, and ρᵣ is the sheet resistivity at r. Here, arc length has the conventional definition of the distance along the curve measured from some fixed reference point.

Inverting voltage into sheet resistivities using Kirchoff's law or its extension into zero line integrals is known as an ill-posed (unstable) problem: small changes in voltages produce large changes in resistivities. Solving the line integrals for each curve CC using a standard mathematical approach will result in calculated resistivities with oscillatory behavior. Error present in the measurements is amplified by the instability of the equations to the point where the resultant calculated resistivities cannot be used with any reasonable degree of confidence. The description will now focus on the regularization techniques used to stabilize the calculations.

According to Kirchoff's current law, if the measured voltages are exact and no other errors are present, a calculation of sheet resistivities ρᵣ using the formula [Equation 2]:

$${∮}_{C} \frac{1}{{ρ}_{r}} {( \frac{ⅆ u}{ⅆ {s}_{n}} )}_{r} ⅆ s - {S}_{C} = 0$$

for each curve CC will produce exact sheet resistivities. In reality, since many errors are inherent in the process, the calculated Jₙₑₜ(u) will frequently have non-zero positive and negative values which result in the above-described oscillatory calculated sheet resistivities ρ. Under these circumstances, mathematicians apply techniques to “regularize” the error (stabilize the calculation) and arrive at a more useful estimate of the true value of the unknown being calculated, in this case sheet resistivity ρ between nodes.

One useful regularization model is that incorporated into a standard least squares minimization model. For a grid comprised of M number of nodes in each left to right row of nodes and N number of nodes in each top to bottom column of nodes, the calculated Jₙₑₜ(u) for each possible curve CC is squared (to eliminate negative values and produce a differentiable error function) and the resulting values are summed. The resulting least squares error minimization term is as follows [Equation 3]:

$$E = {\sum }_{\# d a t a s e t s} [ {\sum }_{C u r v e s C} {( {J}_{n e t} ( u ) )}^{2} ]$$

Here, the summation Σ of the number of datasets (“# datasets”) comprises one dataset for each iteration of current source/sink as discussed above. The rectangular closed curves CC defining Jₙₑₜ(u) are taken as all possible rectangles which include each of the four corners of the water wall. In this way, all linear dependent terms are weighted equally in the error E.

The computational formulation of the objective function defined by E requires judicious choices of many curves CC on the waterwall as well as an accurate and stable computational formulation for the net current flowing across each curve CC [Equation 4]:

$${∮}_{C} \frac{1}{{ρ}_{r}} {( \frac{ⅆ u}{ⅆ {s}_{n}} )}_{r} ⅆ s - {S}_{C}$$

The success of the model depends on how the rectangles are chosen. Each rectangle encloses at least one interior voltage node, no boundary nodes (nodes on the periphery of the matrix), and every side lies halfway between nodes (See FIG. 4). Starting at interior corner node B, curve CCₖⱼ surrounds nodes NB through (k,j) for k=2, . . . , M−1 and j=2, . . . , N−1. This produces (M−2)(N−2) rectangles. Repeating this for each corner produces a total of 4(M−2)(N−2) rectangles for each data set. This provides many more terms than required for the unique solution of the M×N unknown sheet resistivities {ρₖⱼ; k=1, M; j=1, N} that minimize E. However, the use of so many rectangles provides curves both including and excluding current source and sink locations that give the greatest source of error. Furthermore, this large number minimizes the variability inherent in the voltage measurements.

The formula for Jₙₑₜ(u) defines the integral exactly in terms of voltage gradient. This allows any numerical integration scheme to be used. The illustrated numerical evaluation of the line integral around each rectangle uses cubic spline quadrature at the point r midway between voltage nodes. This has the advantage of simulating the existence of a finer voltage mesh between measured voltages, as well as approximating any missing voltages with cubic spline interpolation. The gradient du/dsₙ between nodes normal to the side is approximated by Δu_{d}/Δsₙ where Δu_{d} is the measured voltage drop across the nodes and Δsₙ the distance between nodes.

A steepest descent numerical method is preferably applied to the least squares error minimization term to find sheet resistivities that minimize the value of E. It can be recognized that as E approaches zero, the accuracy of the resulting calculated sheet resistivities ρ increases. Significant instability may still be present in calculations just described. Regularization is necessary to stabilize the calculations.

The unknown sheet resistivities ρ can be imagined as continuous piecewise straight lines projecting in the x and y directions from each node in the matrix. The first difference ∇ of a straight line is equal to the slope of the line. The second difference ∇² of a straight line is zero. For a straight line spanning three equidistantly spaced points x₁, x₂, x₃ parallel to the x axis, the second difference ∇ₓ²ρₓ can be expressed by [Equation 5]:

$$\frac{{ρ}_{{x}_{1}} - 2 {ρ}_{{x}_{2}} + {ρ}_{{x}_{3}}}{Δ {x}^{2}} \approx {∇}_{x}^{2} {ρ}_{x}$$

Here, Δx is the distance between nodes and ρₓ is the unknown sheet resistivity parallel to the x axis. The same approach is applied to a line representing the sheet resistivity in the y direction to arrive at an estimate of the second derivative ∇_{y}²ρₓ. Only ρₓ is used to simplify the equations since ρ_{y}=ρₓ/R where R is a constant representing the ratio between ρₓ and ρ_{y}. The squared second differences are then used in a second level error minimization term as follows [Equation 6]:

$$[ {( {∇}_{x}^{2} {ρ}_{x} )}^{2} + {( {∇}_{y}^{2} {ρ}_{x} )}^{2} ]$$

If both of the estimated second differences (∇ₓ²ρₓ,∇_{y}²ρₓ) are close to zero, the oscillatory behavior of the solution is damped and the solution is stabilized. This presents another opportunity to apply computer-aided optimization.

The second level error minimization term above is multiplied by a constant γ, referred to as a regularization constant, and added to the least squares error minimization term to produce the following regularization model [Equation 7]:

$$E = {\sum }_{\# d a t a s e t s} [ {\sum }_{C u r v e s C} {( {J}_{n e t} ( u ) )}^{2} ] + γ {\sum }_{k , j = 1}^{M - 1 , N - 1} [ {( {∇}_{x}^{2} {ρ}_{x} )}^{2} + {( {∇}_{y}^{2} {ρ}_{x} )}^{2} ]$$

The regularization constant γ permits adjustment of the weight afforded the second level error minimization term in the overall regularization model. The second level error minimization term has the effect of transforming oscillations into locally linear behavior without degrading the global solution behavior.

A further refinement to the regularization model recognizes that the sheet resistivities ρₓ, ρ_{y} may not be locally linear. If the sheet resistivities between nodes are imagined as locally parabolic, then the parabolas will be defined by a quadratic equation. The third difference ∇³ of a quadratic equation is zero. The quadratic equation approximating the parabolic sheet resistivity at a point r₁ requires data from four equally spaced nodes parallel to the x axis (x₁, x₂, x₃, x₄) and can be expressed as follows [Equation 8]:

$$\frac{- {ρ}_{{x}_{1}} + 3 {ρ}_{{x}_{2}} - 3 {ρ}_{{x}_{3}} + {ρ}_{{x}_{4}}}{Δ {x}^{3}} \approx {∇}_{x}^{3} {ρ}_{x}$$

The same approach is applied to a sequence of nodes extending in the y direction to arrive at an estimate of the third derivative ∇_{y}³ρₓ. Again, only ρₓ is used to simplify the equations as explained above. Computer aided error minimization can be applied to the squared results to produce a third level error minimization term [Equation 9]:

$$[ {( {∇}_{x}^{3} {ρ}_{x} )}^{2} + {( {∇}_{y}^{3} {ρ}_{x} )}^{2} ] \approx 0$$

The third level error minimization term may be incorporated into a regularization model as follows [Equation 10]:

$$E = {\sum }_{\# d a t a s e t s} [ {\sum }_{C u r v e s C} {( {J}_{n e t} ( u ) )}^{2} ] + γ {\sum }_{k , j = 1}^{M - 2 , N - 2} [ {( {∇}_{x}^{3} {ρ}_{x} )}^{2} + {( {∇}_{y}^{3} {ρ}_{x} )}^{2} ]$$

Ideally, measured voltages Δu will be available for each voltage node in a matrix so that four consecutive voltage measurements Δu can be incorporated into the estimate of each third level error minimization term.

In the field, voltage data may be incomplete. In accordance with a significant aspect of the invention, when the data required for a third level error minimization term is unavailable, the second level error minimization term is substituted into the regularization model. The resulting “hybrid” regularization model is more accurate than if the incomplete third level terms were left out of the model.

The value of γ should be determined to make the first and second terms equally accurate. Under laboratory conditions, a value of 1 for a grid-normalized value of γ has produced good results. A value of 1 gives the second or third level error minimization term a weight in the regularization model equal to that of the first term. In the field, the value of constant γ can be adjusted as needed to increase or decrease the effect of the second or third level error minimization terms on the regularization model.

The regularization model for electrical resistance mapping as disclosed above is preferably incorporated into an online combustion vessel monitoring system. The hardware components of an online combustion vessel monitoring system include a system computer 62 which may be, for example, a PC (personal computer) based data processing device as shown in FIG. 1 and a conventional voltage data collecting device 64 for collecting voltage data from the node matrix 34 arranged on the wall of the combustion vessel. The conventional voltage data collection device 64 preferably comprises a data collection module which includes switching means and measurement means for iteratively applying a plurality of current source/sink configurations to the matrix 50 shown in FIG. 3 and, for each iteration of source/sink, collecting voltage data corresponding to the voltage drops between each node in the matrix.

Voltage data is fed to the system computer 62 where a systems program organizes the collected data in a digital format. The systems program interacts with several subroutines resident in the system computer 62. The above-disclosed regularization model for electrical resistance mapping is part of a subroutine identified as the electrical resistance mapping (ERM) subroutine. In the ERM subroutine, the voltage data is plugged into the three primary equations of the regularization model to form objective functions. The ERM subroutine accesses an optimization subroutine that preferably applies steepest descent numerical methods to the objective functions. In accordance with the present invention the steepest descent numerical method operates to approach, or converge on, a predetermined level of error E.

A steepest numerical method must begin with an accurate estimate of the unknown, in this case sheet resistivity ρ. The estimate of ρ used in the optimization subroutine is calculated by dividing the resistivity of the material used to construct the wall of the combustion vessel by the thickness of the wall of the combustion vessel. The resistivity in Ω-cm is divided by the nominal waterwall thickness in cm to produce an estimated ρ. The estimated ρ is plugged into the objective functions as a starting point for the steepest descent numerical methods applied by the optimization subroutine.

Another value which must be established prior to application of the steepest descent numerical methods in the optimization subroutine is an acceptable level of error E in the regularization model. In accordance with one aspect of the present invention, an acceptable level of error E is identical with the error in voltage measurements. In application, the value of E is 1/10,000 or 0.0001 signifying four digits of accuracy in the measurement of voltage. The value of 0.0001 also acknowledges the fact that the accuracy of the resulting calculations do not improve significantly beyond a certain low level of E.

Now the optimization subroutine has all the information it needs to apply the steepest descent numerical method to the objective function and arrive at calculated values of sheet resistivity ρ. Calculated sheet resistivities ρ are used by the ERM subroutine to predict the temperature or wastage of the water wall, depending on the particular installation. Temperature and/or wastage data is fed to the systems computer 62, which formats the data into user friendly graphical or numerical displays. Of course, results indicating a hazardous condition can trigger audiovisual alarms and/or automatic shutdown of the affected combustion vessel.

While a preferred embodiment of the foregoing invention has been set forth for purposes of illustration, the foregoing description should not be deemed a limitation of the invention herein. Accordingly, various modifications, adaptations and alternatives may occur to one skilled in the art without departing from the spirit and the scope of the present invention.

What is claimed is:

1. A method for calculating the resistivity of an ohmic material from voltage data gathered from a matrix of nodes arranged on the ohmic material by iteratively imposing a known current to the matrix and measuring voltage at the nodes, each said iteration of imposing a known current resulting in a set of measured voltages, said measured voltages including error E, said method comprising the steps of:
preparing a data set from said measured voltages, said data set comprising voltage drops Δu between nodes;
applying said voltage drops Δu as known variable inputs to an equation that models the ohmic material in two dimensions according to physical laws, said equation also including terms representative of a plurality of unknown resistivities and having a solution equal to zero if said equation contains accurate values of said unknown resistivities and no error E is present;
selecting an acceptable value for E; and
regularizing said equation to stabilize a value of said unknown resistivities calculated using said equation,
wherein said step of regularizing comprises:
adding a regularization term to said equation, said regularization term comprising a selected regularization constant γ multiplied by a third level error minimization term; and
incorporating said equation and said third level error minimization term into a least squares minimization model and using computer-based numerical methods to solve for values of resistivity that result in a global solution to the least squares minimization model below said acceptable value of E.

2. The method of claim 1, wherein said equation applies Kirchoff's law to a selected closed rectangular curve CC surrounding at least one node, said equation comprising:
$${J}_{n e t} ( u ) = {∮}_{C} i ( s ) ⅆ n - {S}_{C} = {∮}_{C} \frac{1}{{ρ}_{r}} {( \frac{ⅆ u}{ⅆ {s}_{n}} )}_{r} ⅆ s - {S}_{C} = 0$$
where r is any point on CC at arc length S, i(s) is the current at arc length s on CC flowing in the direction of the outer normal n to CC, S_{C} is the sum of all current source/sinks within CC, du/dsₙ is the voltage gradient normal to the curve at point r, and ρᵣ is the sheet resistivity at r.

3. The method of claim 1, wherein said acceptable value for E is identical with the error in voltage measurement.

4. The method of claim 1, wherein said equation is used to evaluate all possible curves CC selected to include each of the four internal corner nodes of the matrix.

5. The method of claim 1, wherein said regularization constant γ is determined so that all terms in the error have equal accuracy.

6. The method of claim 1, wherein said third level error minimization term models said resistivity as a local parabola extending through four adjacent nodes and said third level error minimization term comprises an estimate of a third derivative of said parabola.

7. The method of claim 6, wherein said estimate is defined by the equation:
$$\frac{- {ρ}_{{x}_{1}} + 3 {ρ}_{{x}_{2}} - 3 {ρ}_{{x}_{3}} + {ρ}_{{x}_{4}}}{Δ {x}^{3}} \approx {∇}_{x}^{3} {ρ}_{x}$$
where x₁, x₂, x₃, x₄ are four equally spaced nodes parallel to an x or y axis of the matrix Δx is the distance between nodes and ρₓ is the unknown resistivity.

8. The method of claim 1, wherein said regularization term comprises a second level error minimization term requiring less data than said third level error minimization term and said step of regularizing further comprises:
substituting said second level error minimization term for said third level error minimization term when there is insufficient data for said third level error minimization term.

9. The method of claim 8, wherein said second level error minimization term models said resistivity as piecewise straight lines extending through three adjacent nodes and said second level error minimization term comprises an estimate of a second derivative of said straight lines.

10. The method of claim 9, wherein said second level error minimization term is defined by the equation:
$$\frac{{ρ}_{{x}_{1}} - 2 {ρ}_{{x}_{2}} + {ρ}_{{x}_{3}}}{Δ {x}^{2}} \approx {∇}_{x}^{2} {ρ}_{x}$$
where x₁, x₂, x₃ are three equidistantly spaced points parallel to the x or y axis, Δx is the distance between nodes and ρₓ is the unknown resistivity.

11. A computerized method for regularizing an optimization of a sheet resistivity calculation in an on-line combustion vessel monitoring system, said method comprising the steps of:
adding a regularization term to the calculation prior to optimization, said regularization term comprising:
a regularization constant γ multiplied by a third level error minimization term, said third level error minimization term models said sheet resistivity as a parabola extending through four adjacent nodes of a measurement matrix and said third level error minimization term comprises an estimate of a third derivative of said parabola.

12. The method of claim 11, wherein said estimate is defined by the equation:
$$\frac{- {ρ}_{{x}_{1}} + 3 {ρ}_{{x}_{2}} - 3 {ρ}_{{x}_{3}} + {ρ}_{{x}_{4}}}{Δ {x}^{3}} \approx {∇}_{x}^{3} {ρ}_{x}$$
where x₁, x₂, x₃, x₄ are four equally spaced nodes parallel to an x or y axis of the matrix Δx is the distance between nodes and ρₓ is the unknown sheet resistivity.

13. The method of claim 11, wherein said regularization term comprises a second level error minimization term requiring less data than said third level error minimization term and said step of adding further comprises:
substituting said second level error minimization term for said third level error minimization term when there is insufficient data for said third level error minimization term but sufficient data for said second level error minimization term.

14. The method of claim 13, wherein said second level error minimization term models said sheet resistivity as a straight line extending through three adjacent nodes and said second level error minimization term comprises a second estimate of a second derivative of said line.

15. The method of claim 14, wherein said second level error minimization term is defined by the equation:
$$\frac{{ρ}_{{x}_{1}} - 2 {ρ}_{{x}_{2}} + {ρ}_{{x}_{3}}}{Δ {x}^{2}} \approx {∇}_{x}^{2} {ρ}_{x}$$
where x₁, x₂, x₃ are three equidistantly spaced points parallel to the x or y axis, Δx is the distance between nodes and ρₓ is the unknown resistivity.

16. A method for evaluating data representing the electrical characteristics of a combustion vessel, the combustion vessel being operable to combust a fuel, comprising:
preparing a data set based on voltage data gathered from a matrix of nodes arranged on an ohmic material of the combustion vessel including calculating the resistivity of the ohmic material by iteratively imposing a known current to the matrix and measuring voltage at the nodes, each said iteration of imposing a known current resulting in a set of measured voltages, said measured voltages including error E, said data set comprising voltage drops Δu between nodes;
applying said voltage drops Δu as known variable inputs to an ohmic material model which takes into account a plurality of unknown resistivities;
selecting an acceptable value for E; and
regularizing said model to stabilize a value of said unknown resistivities calculated using said model.

17. A method for evaluating data representing the electrical characteristics of a combustion vessel according to claim 16 wherein the ohmic material model has a solution equal to zero in the event that said model contains accurate values of said unknown resistivities and no error E is present and said step of regularizing includes adding a regularization term to said equation, said regularization term comprising a selected regularization constant γ multiplied by a third level error minimization term and incorporating said equation and said third level error minimization term into a least squares minimization model and using computer-based numerical methods to solve for values of resistivity that result in a global solution to the least squares minimization model below said acceptable value of E.
